(19) United States
(12) Patent Application Publication
(10) Pub. No.: US 2012/0134460 A1
(43) Pub. Date: May 31, 2012

(54) LAYOUT STRUCTURE OF SHIFT REGISTER CIRCUIT

(75) Inventors: Ying-Chen CHEN, Hsin-Chu (TW); Hao-Chieh Lee, Hsin-Chu (TW); Chun-Huan Chang, Hsin-Chu (TW); Chun-Hsin Liu, Hsin-Chu (TW); Wan-Jung Chen, Hsin-Chu (TW)

(73) Assignee: AU OPTRONICS CORP., Hsinchu (TW)

(21) Appl. No.: 13/090,593

(22) Filed: Apr. 20, 2011

(30) Foreign Application Priority Data
Nov. 30, 2010 (TW) 099141462

(51) Int. Cl. G11C 19/00

(52) U.S. Cl. 377/78; 377/64

(57) ABSTRACT

An exemplary layout structure of a shift register circuit includes a first shift register and a second shift register arranged adjacent to the first shift register. The first shift register and the second shift register each receive a first signal and a second signal phase-inverted with respect to the first signal. Moreover, the first shift register and the second shift register share a common signal routing trace for receiving the first signal. The common signal routing trace is arranged extending into between the first shift register and the second shift register.

### FIELD OF THE INVENTION

The present invention relates to the semiconductor manufacturing process field, and more particularly to a layout structure of a shift register circuit.

### BACKGROUND OF THE INVENTION

Nowadays, flat panel display devices e.g., liquid crystal display devices have many advantages of high display quality, small volume, light weight and wide application range and thus are widely used in consumer electronics products such as mobile phones, laptop computers, desktop computers and televisions, etc. Moreover, the liquid crystal display devices have evolved into a mainstream display in place of cathode ray tube (CRT) displays.

In a conventional liquid crystal display panel, a gate driving circuit and a source driving circuit are provided to respectively supply gate driving pulse signals and display data signals, and thereby achieving the purpose of image display. In such gate driving circuit or source driving circuit, a shift register circuit is generally provided for signal shifting and registering. For example, a gate-on-array (GOA) type gate driving circuit is different from a chip type gate driving circuit and directly integrated in a display array substrate of the display panel. In such GOA type gate driving circuit, multiple cascaded shift registers are included therein and subjected to the control of multi-phase clock signals such as two-phase clock signals to determine an output timing sequence of the gate driving pulse signals.

However, in the conventional circuit design of shift register circuit, signal routing traces for transmitting clock signals are individually connected to the respective shift registers in the shift register circuit and thus occupy much layout space. Therefore, along with the miniaturization trend of display products has become increasingly prominent and/or the circuit integration is progressively increased, the circuit layout space correspondingly is reduced, which would inevitably result in the circuit design encounters the issue of insufficient layout space.

### SUMMARY OF THE INVENTION

Therefore, the present invention is directed to a layout structure of a shift register circuit, in order to solve the issue of circuit design encountering insufficient layout space in the prior art or improve the circuit layout density.

More specifically, a layout structure of a shift register circuit in accordance with an embodiment of the present invention includes a first shift register and a second shift register. In the illustrative embodiment, the first shift register is electrically connected to receive a first signal and a second signal. The first signal and the second signal are phase-inverted with each other, for example, the first and second signals are phase-inverted two clock signals. The second shift register is electrically connected to receive the first signal and the second signal. The second shift register is arranged adjacent to the first shift register. The first shift register and the second shift register share a first signal routing trace to receive the first signal. The first signal routing trace is arranged extending into between the first shift register and the second shift register.

In one embodiment, the layout structure further includes a third shift register. The third shift register is electrically connected to receive the first signal and the second signal. The third shift register is arranged adjacent to the second shift register and whereby the second shift register is located between the first shift register and the third shift register. Moreover, the third shift register and the second shift register share a second signal routing trace to receive the second signal. The second signal routing trace is arranged extending into between the third shift register and the second shift register. In an alternative embodiment, the first shift register, the second shift register and the third shift register are electrically connected to receive the second signal through different second signal routing traces respectively.

In one embodiment, a terminal of the first signal routing trace extending into between the first shift register and the second shift register is linearly connected to the second shift register and laterally extends to connect with the first shift register.

In one embodiment, the layout structure further includes a first bus line and a second bus line respectively for providing the first signal and the second signal. The first bus line and the second bus line are arranged in parallel.

A layout structure of a shift register circuit in accordance with another embodiment of the present invention includes a first bus line, a second bus line, multiple shift registers and a signal routing trace. At least one of the first bus line and the second bus line is for providing an alternating current (AC) signal e.g., a clock signal. The signal routing trace is arranged extending from the first bus line and crossing the second bus line and then divided into multiple branches to respectively electrically connect with the shift registers. The remained one of the first bus line and the second bus line is for providing a direct current (DC) signal, or another AC signal e.g., another clock signal instead.

In the above various embodiments of the present invention, the adjacent two shift registers are electrically connected to a common signal routing trace and thus the space occupied by signal routing traces can be saved, which would relieve the issue of insufficient circuit layout space in some degree or improve the circuit layout density. In addition, multiple shift registers share the common signal routing trace arranged crossing the bus line (herein, at least one of the crossed bus line and the signal routing trace is for providing an AC signal), compared with the prior art that multiple signal routing traces are individually connected to respective shift registers, a parasitic capacitance formed between the signal routing trace and the crossed bus line can be dramatically reduced, so that the power consumption is improved.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic principle diagram of a layout structure of a shift register circuit in accordance with an embodiment of the present invention.

FIG. 2 is a partial simplified view of the layout structure of the shift register circuit in FIG. 1.

FIG. 3 is a schematic principle diagram of a layout structure of a shift register circuit in accordance with another embodiment of the present invention.

FIG. 4 is a schematic principle diagram of a layout structure of a shift register circuit in accordance with still another embodiment of the present invention.

FIG. 5 is a schematic principle diagram of a layout structure of a shift register circuit in accordance with even still another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

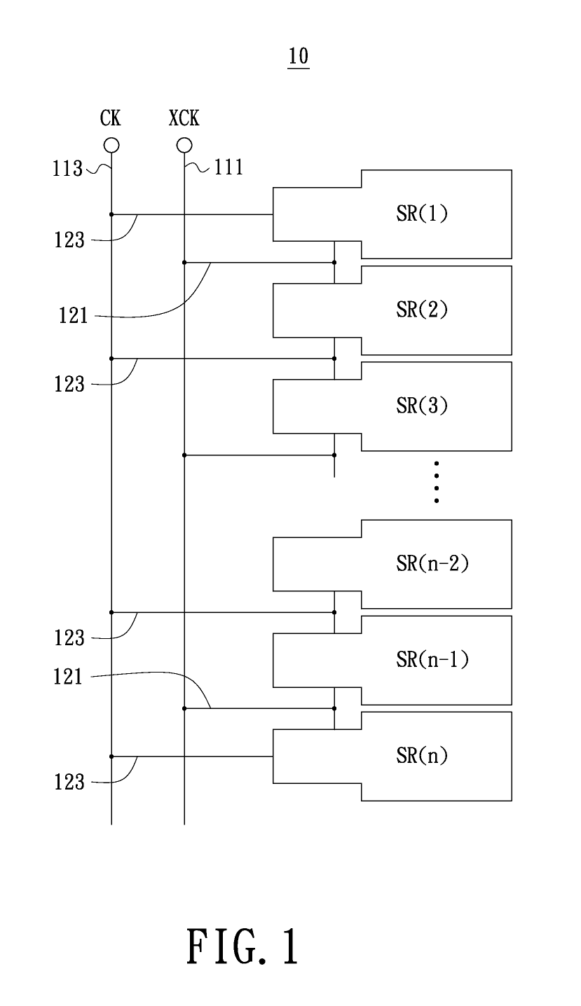

Referring to FIG. 1, a schematic principle diagram of a layout structure of a shift register circuit in accordance with an embodiment of the present invention is shown. As illustrated in FIG. 1, the shift register circuit 10 includes shift registers SR(1), SR(2), SR(3), . . . , SR(n−2), SR(n−1), SR(n), signal routing traces 121, 123 and parallel-arranged bus lines 111, 113, where n is a positive integer greater than 1. In the illustrative embodiment, the shift register circuit 10 can be applied in a GOA type gate driving circuit of display device, but it is not to limited to the present invention, and can be applied in other driving circuits such as a chip type gate driving circuit or a chip type source driving circuit, etc.

Each of the shift registers SR(1), SR(2), SR(3), . . . , SR(n−2), SR(n−1), SR(n) is electrically connected to receive clock signals XCK, CK. Each adjacent two of the shift registers SR(1), SR(2), SR(3), . . . , SR(n−2), SR(n−1), SR(n) share a signal routing trace, i.e., are electrically connected to a common signal routing trace. For example, the adjacent-arranged shift registers SR(1) and SR(2) share the signal routing trace 121 to receive the clock signal XCK provided from the bus line 111, and the shared signal routing trace 121 is arranged extending into between the shift registers SR(1) and SR(2) to form electrical connections with both the shift registers SR(1) and SR(2). The adjacent-arranged shift registers SR(2) and SR(3) share the signal routing trace 123 to receive the clock signal CK provided from the bus line 113, and the shared signal routing trace 123 is arranged extending into between the shift registers SR(2) and SR(3) to form electrical connections with the shift registers SR(2) and SR(3). In the illustrative embodiment, the shift register SR(2) is arranged between the shift registers SR(1) and SR(3).

Similarly, the adjacent-arranged shift registers SR(n−2) and SR(n−1) share the signal routing trace 123 to receive the clock signal CK provided from the bus line 113, and the shared signal routing trace 123 is arranged extending into between the shift registers SR(n−2) and SR(n−1) to form electrical connections with both the shift registers SR(n−2) and SR(n−1). The adjacent-arranged shift registers SR(n−1) and SR(n) share the signal routing trace 121 to receive the clock signal XCK provided from the bus line 111, and the shared signal routing trace 121 is arranged extending into between the shift registers SR(n−1) and SR(n) to form electrical connections with the shift registers SR(n−1) and SR(n). In the illustrative embodiment, the shift register SR(n−1) is arranged between the shift registers SR(n−2) and SR(n).

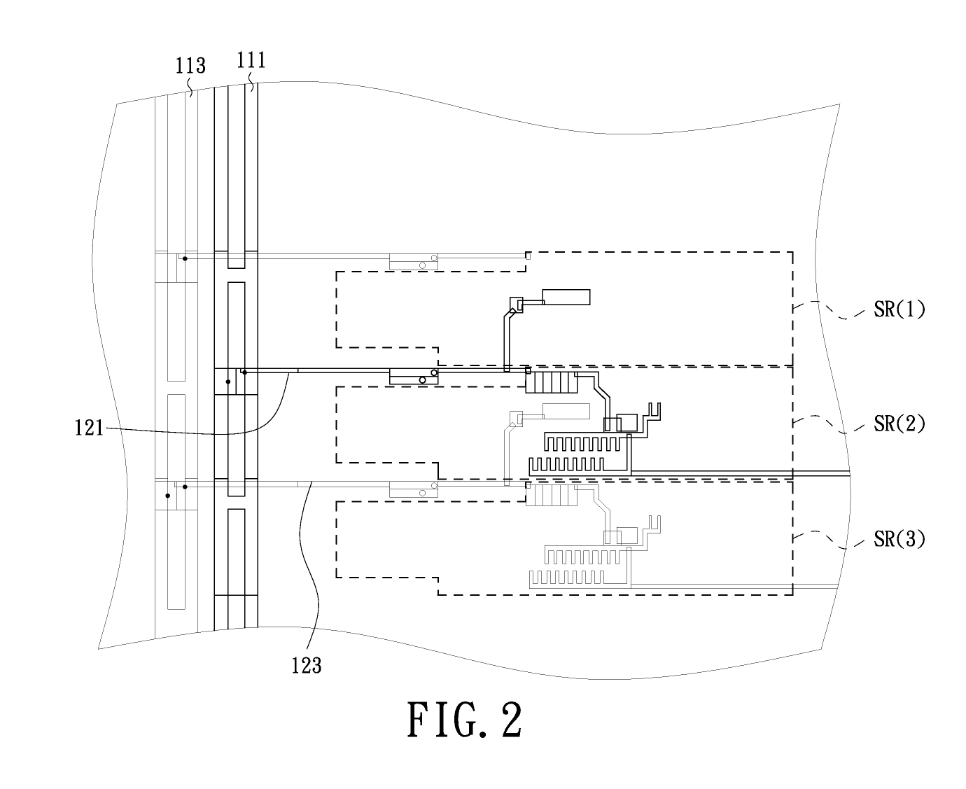

Referring to FIG. 2, a partial simplified view of the layout structure of the shift register circuit in FIG. 1 is shown. As illustrated in FIG. 2, a terminal of the shared signal routing trace 121 arranged extending into between the shift registers SR(1) and SR(2) is electrically connected to the bus line 111, and another terminal of the shared signal routing trace 121 extends into between the shift registers SR(1) and SR(2) to linearly connect with the shift register SR(2) and further laterally extends to connect with the shift register SR(1). Similarly, a terminal of the shared signal routing trace 123 arranged extending into between the shift registers SR(2) and SR(3) is electrically connected to the bus line 113, and another terminal of the shared signal routing trace 123 extends into between the shift registers SR(2) and SR(3) to linearly connect with the shift register SR(3) and further laterally extends to connect with the shift register SR(2).

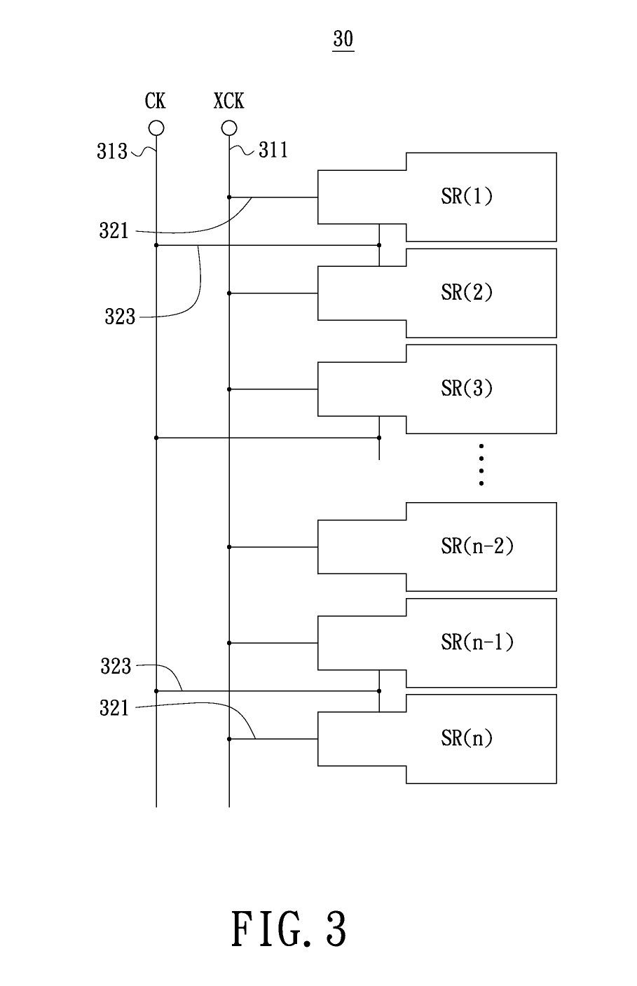

It is indicated that, the signal routing traces in the present invention is not limited to the implementation illustrated in FIG. 1, and can be other implementations, e.g., as illustrated in FIG. 3.

Referring to FIG. 3, a schematic principle diagram of a layout structure of a shift register circuit in accordance with another embodiment of the present invention is shown. As illustrated in FIG. 3, each of shift registers SR(1), SR(2), SR(3), . . . , SR(n−2), SR(n−1), SR(n) is electrically connected to receive clock signals XCK, CK. Adjacent two of the shift registers SR(1), SR(2), SR(3), . . . , SR(n−2), SR(n−1), SR(n) only share a signal routing trace 323 for transmitting the clock signal CK. In particular, for instance, the adjacent-arranged shift registers SR(1) and SR(2) share the signal routing trace 323 to receive the clock signal CK provided from a bus line 313, and the shared signal routing trace 323 is arranged extending into between the shift registers SR(1) and SR(2) to form electrical connections with the shift registers SR(1) and SR(2), but the shift registers SR(1) and SR(2) are electrically connected receive the clock signal XCK provided from another bus line 311 through respective different signal routing lines 321. The adjacent-arranged shift registers SR(2) and SR(3) do not share any signal routing trace and are electrically connected to receive the clock signal XCK provided from the bus line 311 through respective different signal routing signals 321. In the illustrative embodiment, the shift register SR(2) is arranged between the shift registers SR(1) and SR(3), and the bus lines 311 and 322 are arranged in parallel.

Similarly, the adjacent-arranged shift registers SR(n−2) and SR(n−1) do no share any signal routing trace and are electrically connected to receive the clock signal XCK provided form the bus line 311 through respective different signal routing traces 321. The adjacent-arranged shift registers SR(n−1) and SR(n) share the signal routing trace 323 to receive the clock signal CK provided from the bus line 313, and the shared signal routing trace 323 is arranged extending into between the shift registers SR(n−1) and SR(n) to form electrical connections with the shift registers SR(n−1) and SR(n). The shift registers SR(n−1) and SR(n) are electrically connected to receive the clock signal XCK provided from the bus line 311 through respective different signal routing traces 321. In the illustrative embodiment, the shift register SR(n−1) is arranged between the shift registers SR(n−2) and SR(n).

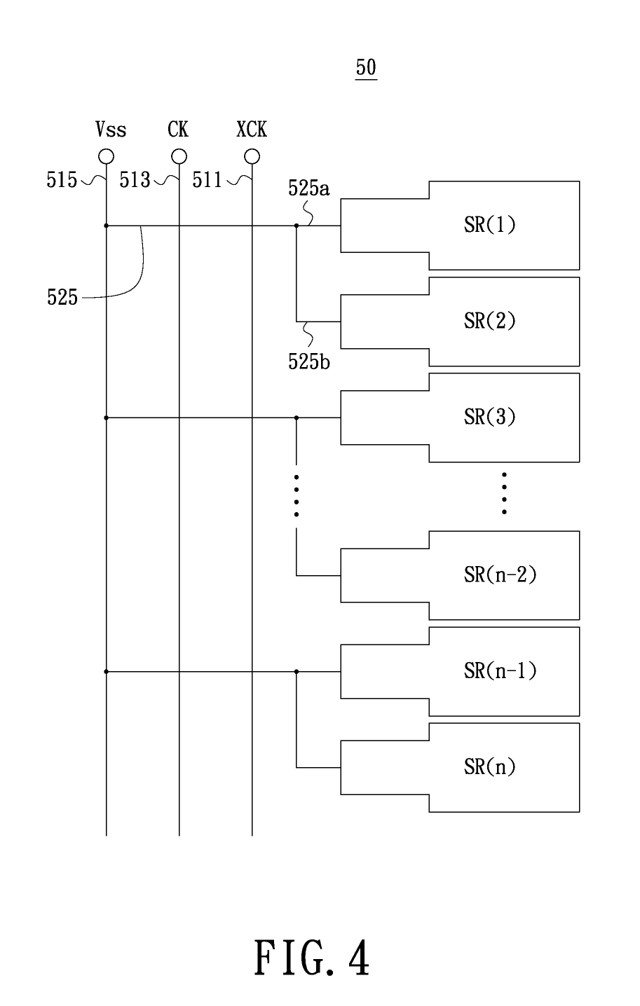

In addition, it also can be found from the embodiments as illustrated in FIGS. 1 and 3 that: each the signal routing trace 123 in FIG. 1 is arranged extending from the bus line 113 and crossing the bus line 111 for providing the clock signal XCK and then is divided into two branches to respectively connect with two adjacent shift registers e.g., SR(2) and SR(3), or SR(n−2) and SR(n−1). Similarly, each signal routing trace 323 in FIG. 3 is arranged extending from the bus line 313 and crossing the bus line 311 for providing the clock signal XCK and then is divided into two branches to respectively connect with two adjacent shift registers e.g., SR(1) and SR(2), or SR(n−1) and SR(n). Accordingly, compared with the prior art that the signal routing traces are individually connected to the respective shift registers, a total parasitic capacitance between each the signal routing trace 123 (or 323) connected to the bus line 113 (or 313) for providing the clock signal CK and the crossed bus line 111 (or 311) for providing the clock signal XCK is dramatically decreased, and thereby the power consumption is improved. It is indicated that, FIGS. 1 and 3 each only illustrate each the signal routing trace arranged crossing the bus line and the crossed bus line both are for providing alternating current (AC) signals, e.g., the clock signals CK, XCK to the respective shift registers, but it is not to limit the present invention, and can be other implementations, e.g., as illustrated in FIG. 4.

Referring to FIG. 4, a schematic principle diagram of a layout structure of a shift register circuit in accordance with still another embodiment of the present invention is shown. In the illustrative embodiment, FIG. 4 shows multiple cascaded shift registers SR(1), SR(2), SR(3), . . . , SR(n−2), SR(n−1), SR(n), bus lines 511, 513 respectively for providing clock signals XCK, CK, and another bus line 515 for providing a direct current (DC) signal e.g., a grounding level Vss. Adjacent two of the shift registers share the signal routing trace 525. It is indicated that, FIG. 4 omits the electrical connections between the bus lines 511, 513 for providing the clock signals XCK, CK and the shift registers SR(1), SR(2), SR(3), . . . , SR(n−2), SR(n−1), SR(n), and the electrical connections can refer to the electrical connections associated with the bus lines 111, 113 in FIG. 1 or the bus lines 311, 313, but the present invention is not limited to these.

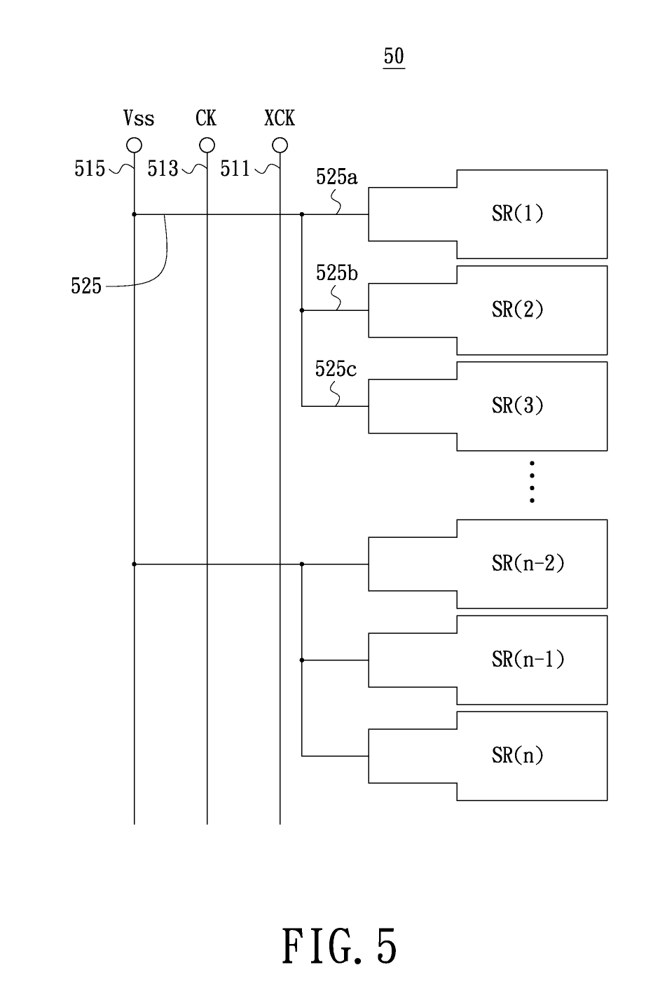

More specifically, a single signal routing trace 525 is arranged extending from the bus line 515 for providing the DC signal e.g., the grounding level Vss and crossing the bus lines 511, 513 for providing AC signals e.g., the clock signals CK, XCK and then is divided into two branches 525a, 525b. In the illustrative embodiment, the two branches 525a, 525b are respectively electrically connected to two adjacent shift registers e.g., SR(1) and SR(2). In addition, it is indicated that, after extending from the bus line 515 and crossing the bus lines 511, 513 for providing AC signals e.g., the clock signals CK, XCK, the single signal routing trace 525 can be divided into more than two branches e.g., three branches 525a, 525b, 525c as illustrated in FIG. 5 instead, and then electrically connected with shift registers with a corresponding amount.

To sum up, in the above various embodiments of the present invention, the adjacent two shift registers are electrically connected to a common signal routing trace and thus the space occupied by signal routing traces can be saved, which would relieve the issue of insufficient circuit layout space in some degree or improve the circuit layout density. In addition, multiple shift registers share the common signal routing trace arranged crossing the bus line (herein, at least one of the crossed bus line and the signal routing trace is for providing an AC signal), compared with the prior art that multiple signal routing traces are individually connected to respective shift registers, a parasitic capacitance formed between the signal routing trace and the crossed bus line can be dramatically reduced, so that the power consumption is improved.

Additionally, the skilled person in the art can apply the layout structure of shift register circuit of the present invention to other application fields except the above-mentioned display field, the above clock signals can be modified to be other type of signals, and such modification(s) ought to be included in the scope of the present invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A layout structure of a shift register circuit, comprising:
a first shift register, electrically connected to receive a first signal and a second signal phase-inverted with respect to the first signal; and
a second shift register, electrically connected to receive the first signal and the second signal and arranged adjacent to the first shift register;
wherein the first shift register and the second shift register shares a first signal routing trace to receive the first signal, and the first signal routing trace is arranged extending into between the first shift register and the second shift register.

2. The layout structure as claimed in claim 1, further comprising:
a third shift register, electrically connected to receive the first signal and the second signal and arranged adjacent to the second shift register so that the second shift register is located between the first shift register and the third shift register;
wherein the third shift register and the second shift register share a second signal routing trace to receive the second signal, and the second signal routing trace is arranged extending into between the third shift register and the second shift register.

3. The layout structure as claimed in claim 1, further comprising:
a third shift register, electrically connected to receive the first signal and the second signal and arranged adjacent to the second shift register so that the second shift register is located between the first shift register and the third shift register;
wherein the first shift register, the second shift register and the third shift register are electrically connected to receive the second signal through different second signal routing traces respectively.

4. The layout structure as claimed in claim 1, wherein a terminal of the first signal routing trace, extending into between the first shift register and the second shift register, is linearly connected to the second shift register and laterally extends to thereby connect with the first shift register.

5. The layout structure as claimed in claim 1, wherein the first signal and the second signal respectively are two phase-inverted clock signals.

6. The layout structure as claimed in claim 1, further comprising:
a first bus line, for providing the first signal; and
a second bus line, for providing the second signal and arranged in parallel with the first bus line.

7. A layout structure of a shift register circuit, comprising:
a first bus line;
a second bus line, wherein at least one of the first bus line and the second bus line is for providing an alternating current signal;
a plurality of shift registers; and
a signal routing trace, arranged extending from the first bus line and crossing with the second bus line and then divided into a plurality of branches to respectively electrically connect with the shift registers after crossing the second bus line.

8. The layout structure as claimed in claim 7, wherein the remained one of the first bus line and the second bus line is for providing a direct current signal.

9. The layout structure as claimed in claim 7, wherein the remained one of the first bus line and the second bus line is for providing another alternating current signal.
